(19) United States
(12) Patent Application Publication
(10) Pub. No.: US 2011/0157149 A1
(43) Pub. Date: Jun. 30, 2011

(54) APPARATUS AND METHOD OF RESETTING ELECTRONIC PAPER PANEL

(75) Inventors: Hee Bum LEE, Suwon (KR); Kyoung Soo CHAE, Suwon (KR); Hwan-Soo LEE, Seoul (KR)

(73) Assignee: SAMSUNG ELECTRO-MECHANICS CO., LTD., Suwon (KR)

(21) Appl. No.: 12/832,421

(22) Filed: Jul. 8, 2010

(30) Foreign Application Priority Data
Dec. 24, 2009 (KR) 1020090131106

(51) Int. Cl. G09G 5/00; H03L 7/00

(52) U.S. Cl. 345/213; 327/142

(57) ABSTRACT

There is provided an apparatus and method of resetting an electronic paper panel. An apparatus for resetting an electronic paper panel according to an aspect of the invention may include: a time control unit determining start and end times of a predetermined reset period on the basis of a frame synchronization signal and a data synchronization signal of an electronic paper panel, and determining start and end times of a predetermined pulse reset period within the reset period; and a driving circuit unit generating a pulse reset signal having pulses with a predetermined frequency during the pulse reset period, determined by the time control unit, and generating a display reset signal during the reset period to thereby supply the pulse reset signal and the display reset signal to the electronic paper panel.

### CROSS-REFERENCE TO RELATED APPLICATIONS

This application claims the priority of Korean Patent Application No. 10-2009-0131106 filed on Dec. 24, 2009, in the Korean Intellectual Property Office, the disclosure of which is incorporated herein by reference.

### BACKGROUND OF THE INVENTION

1. Field of the Invention

The present invention relates to an apparatus and method of resetting an electronic paper panel, and more particularly, to an apparatus and method of resetting an electronic paper panel that improves the movements of balls for resetting a display of an electronic paper panel by supplying a pulse reset signal having a plurality of pulses of alternating positive (+) and negative (−) voltages to the electronic paper panel to thereby eliminate a memory effect such as an afterimage.

2. Description of the Related Art

With the recent advancements in personal digital assistances and data communication networks, there has been a need for the development of apparatuses designed to be conveniently portable. To meet this demand, so-called electronic paper displays have been developed within the field of display devices.

These electronic paper displays are conveniently portable due to their flexibility, can be driven at low voltage, can maintain high definition even after power supply cut-off, and provide high resolution with a wide viewing angle.

As for technical approaches to realize electronic paper displays, a method of using liquid crystals, organic EL displays, reflective-film reflective displays, electrophoretic displays, and electrochromic displays are provided.

In general, an electronic paper display includes an electronic paper panel consisting of a plurality of cells having electrodes and switches, a scan-line driver supplying scan pulse signals to the scan lines of the electronic paper panel, a data-line driver supplying data pulse signals to the data lines of the electronic paper panel, and a controller controlling the data-line driver and the scan-line driver.

According to electrophoretic capsules or twist balls, in order to display content on a screen and subsequently display further content thereupon, an electronic paper panel needs to be reset, and the previous content displayed on the electronic paper needs to be removed.

Here, the twist balls and the electrophoretic capsules are referred to as electronic ink. The electronic ink inside the electronic paper has an electrical polarity so that it is separated into white and black. As the electronic ink moves according to the electrical characteristics being applied to the electronic paper panel, the content can be displayed on the electronic paper panel according to the movement of the electronic ink.

In the related art, a method of resetting an electronic paper panel employs a method of supplying a reset signal merely having a voltage level conversion to an electronic paper panel.

However, as this method of resetting an electronic paper panel according to the related art supplies a reset signal merely having a voltage level conversion, the electronic ink does not move quickly, and thus fails to respond to a reset signal quickly and accurately, thereby producing a memory effect such as an afterimage. As a result, this method ultimately reduces the picture quality of the electronic paper.

### SUMMARY OF THE INVENTION

An aspect of the present invention provides an apparatus and method of resetting an electronic paper panel that improves the movements of balls for resetting a display of an electronic paper panel by supplying a pulse reset signal having a plurality of pulses of alternating positive (+) and negative (−) voltages to the electronic paper panel during a pulse reset period corresponding to a predetermined period partially constituting a predetermined reset period to thereby eliminate a memory effect such as an afterimage.

According to an aspect of the present invention, there is provided an apparatus for resetting an electronic paper panel, the apparatus comprising: a time control unit determining start and end times of a predetermined reset period on the basis of a frame synchronization signal and a data synchronization signal of an electronic paper panel, and determining start and end times of a predetermined pulse reset period within the reset period; and a driving circuit unit generating a pulse reset signal having pulses with a predetermined frequency during the pulse reset period, determined by the time control unit, and generating a display reset signal during the reset period to thereby supply a reset signal having the pulse reset signal and the display reset signal to the electronic paper panel.

The driving circuit unit may include: a scan-line driver supplying scan pulse signals to scan lines of a lower electrode included in the electronic paper panel; and a data-line driver supplying data pulse signals to data lines of the lower electrode included in the electronic paper panel, and supplying an upper electrode signal to an upper electrode of the electronic paper panel, wherein the display reset signal comprises the upper electrode signal having a one-time voltage level transition and the scan pulse signals and the data pulse signals having the same voltage level opposite to that of the upper electrode signal, and the pulse reset signal comprises at least one of the scan pulse signals, the data pulse signals and the upper electrode signal, the at least one signal having a plurality of pulses.

The driving circuit unit may set the pulse reset period to one or more periods within the reset period.

The driving circuit unit may set the pulse reset period to one period between a start point of the reset period and a predetermined time.

The driving circuit unit may set the pulse reset period to two periods consisting of one period between the start point of the reset period and a predetermined time and the other period between a time of the voltage level transition of the scan pulse signals within the reset period and a predetermined time.

The reset period may be set next to the frame synchronization signal or between the data pulse signals.

The driving circuit unit may generate the pulse reset signal comprising the scan pulse signals at a high level corresponding to a positive voltage and one of the data pulse signals and the upper electrode signal, the one signal having a plurality of pulses of alternating positive (+) and negative (−) voltages.

The driving circuit unit may generate the pulse reset signal having a duty cycle varying during the pulse reset period.

The driving circuit unit may generate the pulse reset signal comprising the scan pulse signals at a high level corresponding to a positive voltage and the data pulse signals and the upper electrode signal having a plurality of pulses with voltage levels opposite to each other.

The driving circuit unit may generate the pulse reset signal comprising the data pulse signals and the upper electrode signal having duty cycles varying during the pulse reset period.

The driving circuit unit may generate the pulse reset signal comprising the data pulse signals at a high level corresponding to a positive voltage and a corresponding scan pulse signal, among the scan pulse signals, having a plurality of pulses with a predetermined frequency.

The driving circuit unit may generate the pulse reset signal comprising a corresponding scan pulse signal at a high level corresponding to a positive voltage among the scan pulse signals and a corresponding data pulse signal having a plurality of pulses with a predetermined frequency among the data pulse signals.

According to another aspect of the present invention, there is provided a method of resetting an electronic paper panel, the method including: a reset period determination operation of determining start and end times of a predetermined reset period on the basis of a frame synchronization signal and a data synchronization signal of an electronic paper frame; a reset signal generation operation of generating a reset signal during the reset period determined in the reset period determination operation; a pulse reset period determination operation of determining start and end times of a predetermined pulse reset period within the reset period; and a pulse reset signal generation operation of generating a pulse reset signal having pulses with a predetermined frequency during the pulse reset period determined in the pulse reset period determination operation.

The reset signal generation operation may generate the reset signal comprising the upper electrode signal having a one-time voltage level transition and the scan pulse signals and the data pulse signals having the same voltage level opposite to that of the upper electrode signal.

The pulse reset signal generation operation may generate the pulse reset signal comprising at least one of the scan pulse signals, the data pulse signals and the upper electrode signal, the at least one signal comprising a pulse signal having a plurality of pulses.

The pulse reset period determination operation may set the pulse reset period to one or more periods within the reset period.

The pulse reset period determination operation may set the pulse reset period between a start point of the reset period and a predetermined time.

The pulse reset period determination operation may set the pulse reset period to two periods consisting of one period between a start point of the reset period and a predetermined time and the other period between a time of the voltage level transition of the scan pulse signals within the reset period and a predetermined time.

The reset period may be set next to the frame synchronization signal or between the data pulse signals.

The pulse reset signal generation operation may generate the pulse reset signal comprising the scan pulse signals at a high level corresponding to a positive voltage and one of the data pulse signals and the upper electrode signal, the one signal having a plurality of pulses of alternating positive (+) and negative (−) voltages, when the reset period may be set next to the frame synchronization signal.

The pulse reset signal generation operation may generate the pulse reset signal having a duty cycle varying during the pulse reset period.

The pulse reset signal generation operation may generate the pulse reset signal comprising the scan pulse signals at a high level corresponding to a positive voltage and the data pulse signals and the upper electrode signal having a plurality of pulses with voltage levels opposite to each other when the reset period may be set next to the frame synchronization signal.

In the pulse reset signal generation operation, the data pulse signals and the upper electrode signal may be pulse signals having duty cycles varying during the pulse reset period.

The pulse reset signal generation operation may generate the pulse reset signal comprising the data pulse signals at a high level corresponding to a positive voltage and a corresponding scan pulse signal having a plurality of pulses with a predetermined frequency among the scan pulse signals when the reset period is set between the data pulse signals.

The pulse reset signal generation unit may generate the pulse reset signal comprising a corresponding scan pulse signal at a high level corresponding to a positive voltage among the scan pulse signals and a corresponding data pulse signal having a plurality of pulses with a predetermined frequency among the data pulse signals when the reset period is set between the data pulse signals.

### BRIEF DESCRIPTION OF THE DRAWINGS

The above and other aspects, features and advantages of the present invention will be more clearly understood from the following detailed description taken in conjunction with the accompanying drawings, in which:

FIG. 1 is a block diagram illustrating an apparatus for resetting an electronic paper panel according to an exemplary embodiment of the present invention;

FIG. 2 is a timing chart of a frame synchronization signal, scan pulse signals and data pulse signals according to an exemplary embodiment of the present invention;

FIG. 3 is a structural view illustrating a driving circuit unit, a TFT array, and electrodes according to an exemplary embodiment of the present invention;

FIG. 4 is a view illustrating a first example of display and pulse reset signal according to an exemplary embodiment of the present invention;

FIG. 5 is a view illustrating a second example of display and pulse reset signal according to an exemplary embodiment of the present invention;

FIG. 6 is a view illustrating a first position example of a reset period of an electronic paper panel according to an exemplary embodiment of the present invention;

FIG. 7 is a view illustrating a second position example of a reset period of an electronic paper panel according to an exemplary embodiment of the present invention;

FIG. 8 is an enlarged view illustrating a first example of a pulse reset signal according to an exemplary embodiment to the present invention;

FIG. 9 is an enlarged view illustrating a second example of a pulse reset signal according to an exemplary embodiment to the present invention;

FIG. 10 is an enlarged view illustrating a third example of a pulse reset signal according to an exemplary embodiment to the present invention;

FIG. 11 is an enlarged view illustrating a fourth example of a pulse reset signal according to an exemplary embodiment to the present invention; and

FIG. 12 is a flowchart illustrating a method of resetting an electronic paper panel according to an exemplary embodiment of the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

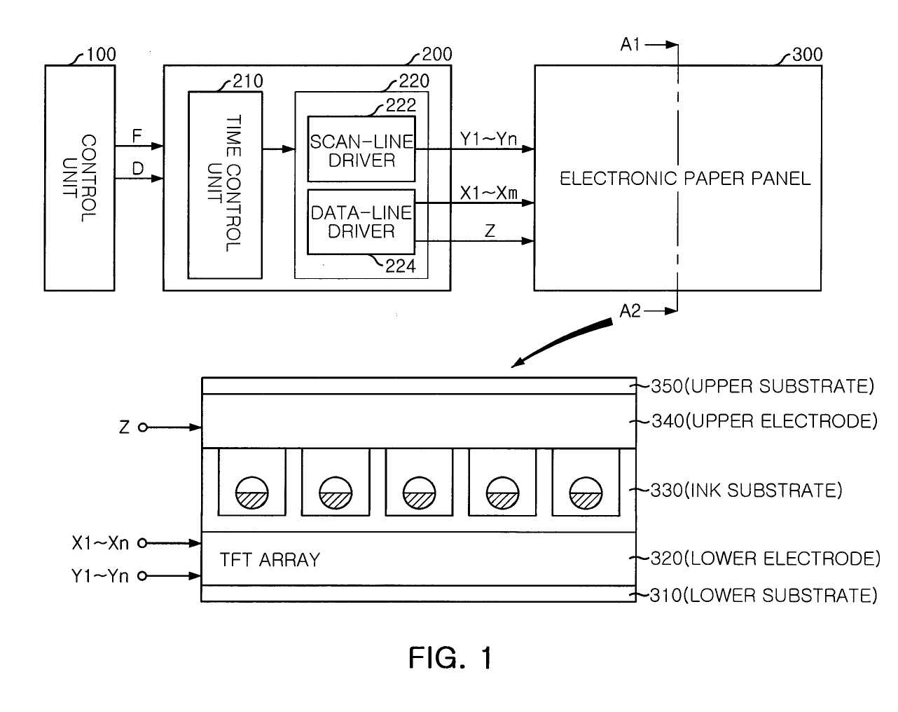

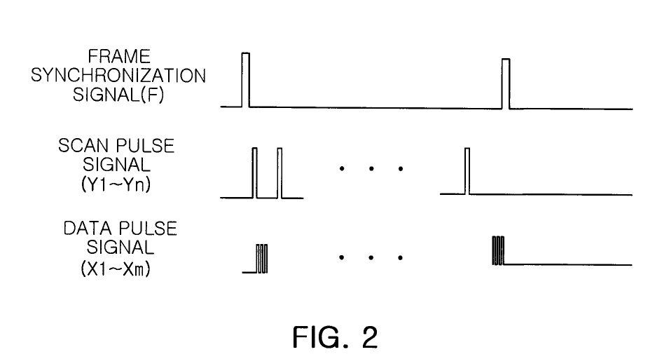

FIG. 1 is a block diagram illustrating an apparatus for resetting an electronic paper panel according to an exemplary embodiment of the invention. FIG. 2 is a timing chart of a frame synchronization signal, scan pulse signals and data pulse signals according to an exemplary embodiment of the invention.

Referring to FIGS. 1 and 2, an apparatus for resetting an electronic paper panel according to an exemplary embodiment of the invention may include a time control unit 210 and a driving circuit unit 220. The time control unit 210 determines the start and end times of a predetermined reset period by using a frame synchronization signal and a data signal of an electronic paper panel, and also determines the start and end times of a predetermined pulse reset period PRP within the reset period. The driving circuit unit 220 generates a pulse reset signal having pulses with a predetermined frequency during the pulse reset period PRP, determined by the time control unit 210, and generates a display reset signal during the reset period to thereby supply a reset signal having the pulse reset signal and the display reset signal to the electronic paper panel.

The time control unit 210 according to this embodiment receives the frame synchronization signal F and the data signal D from the control unit 100, and generates the display reset signal and the pulse reset signal on the basis of the frame synchronization signal F and the data signal D to thereby supply the reset signal having the reset signal and the pulse reset signal to the electronic paper panel.

Here, the display reset signal and the pulse reset signal consist of scan pulse signals Y1 to Ym, data pulse signals X1 to Xn and an upper electrode signal Z.

The driving circuit unit 220 may include a scan-line driver 222 and a data-line driver 224. The scan-line driver 222 supplies the scan pulse signals Y1 to Ym to the scan lines of the electronic paper panel. The data-line driver 224 supplies the data pulse signals X1 to Xn to the data lines of the electronic paper panel and the upper electrode signal Z to an upper electrode of the electronic paper panel.

Here, the display reset signal may consist of the upper electrode signal Z having a one-time voltage level transition, and the scan pulse signals Y1 to Ym and the data pulse signals X1 to Xn having the same voltage level to each other, opposite to that of the upper electrode signal Z.

Furthermore, the pulse reset signal may consist of at least one of the scan pulse signals Y1 to Ym, the data pulse signals X1 to Xn and the upper electrode signal Z, the at least one signal being a pulse signal having a plurality of pulses of alternating positive (+) and negative (−) voltages.

Referring to FIGS. 1 and 2, the electronic paper panel according to this embodiment may include a lower substrate 310, a lower electrode 320 formed on the lower substrate 310 and having a plurality of cells including a TFT array and electrodes, an ink substrate 330 formed on the lower electrode 320 and containing electronic ink, n transparent upper electrode 340 formed on the ink substrate 330, and an upper substrate 350 formed on the upper electrode 340.

Here, the electronic ink may be twist balls or electrophoretic capsules. When the electronic ink is formed of twist balls, the ink substrate 330 may include separation walls formed between the twist balls.

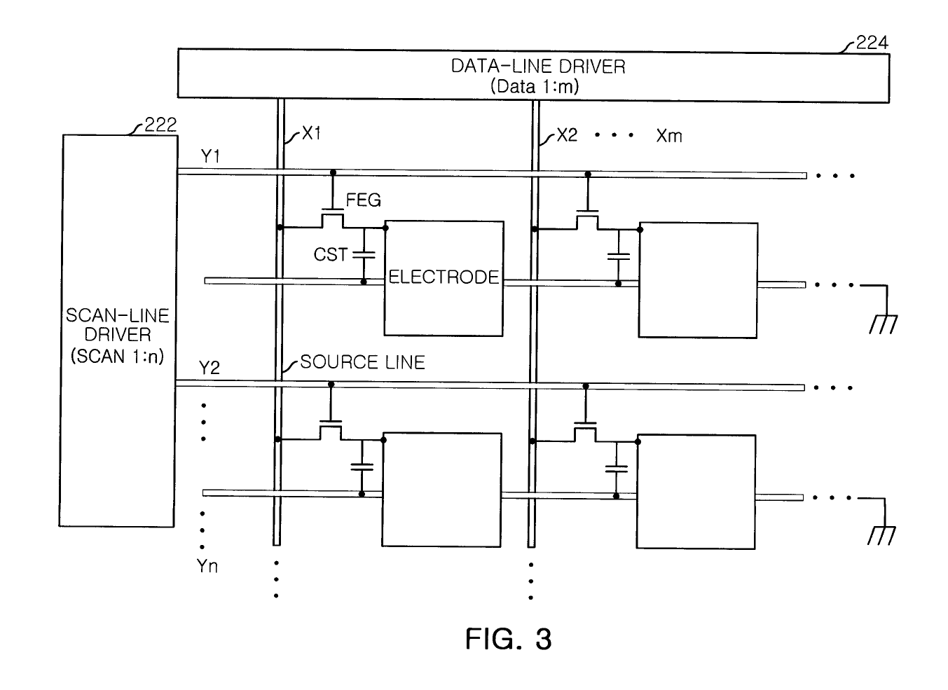

FIG. 3 is a structural view illustrating a driving circuit unit, a TFT array and electrodes of an electronic paper panel according to an exemplary embodiment of the invention. The scan-line driver 222 supplies the scan pulse signals Y1 to Ym to a plurality of scan lines, while the data-line driver 224 supplies the data pulse signals X1 to Xn to a plurality of data lines.

Here, each of the plurality of the lower electrode 320 includes a TFT transistor having a gate connected to the scan line and a source and a drain connected to the data line, a storage capacitor CST connected to a ground and the drain of the TFT transistor, and an electrode connected to the drain of the TFT transistor.

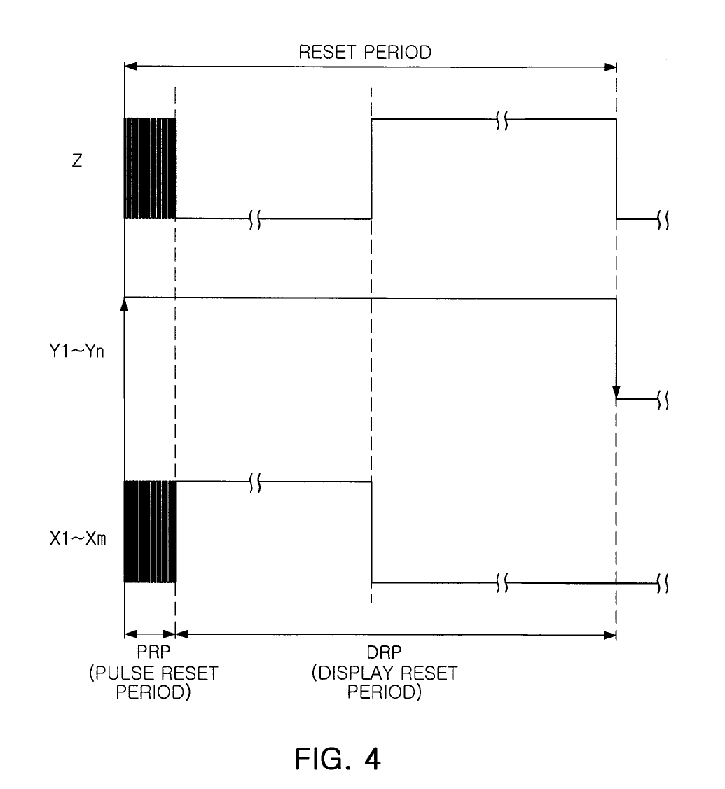

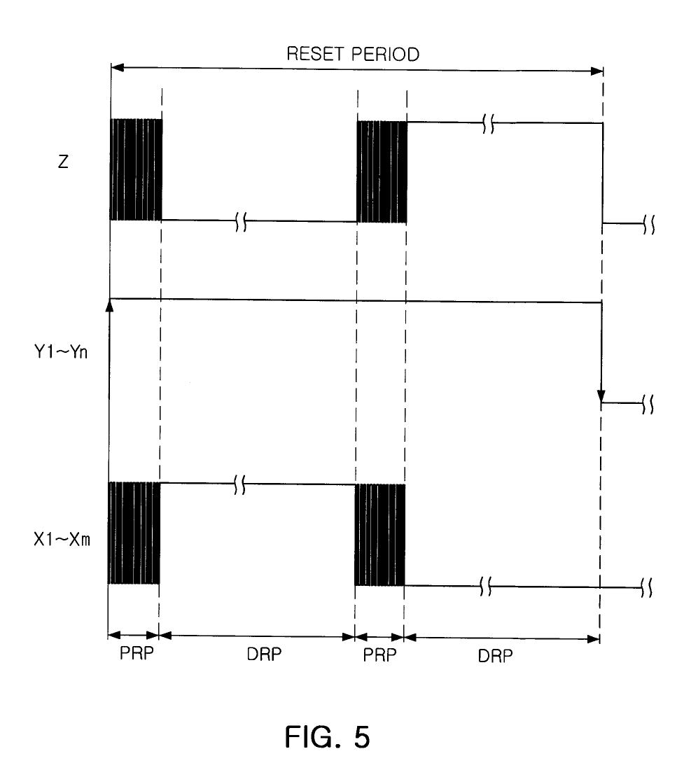

Furthermore, the driving circuit unit 220 may set the pulse reset period PRP to one period within the reset period, which will now be described with reference to FIGS. 4 and 5.

FIG. 4 is a view illustrating display and pulse reset signal according to a first exemplary embodiment of the invention, and FIG. 5 is a view illustrating display and pulse reset signal according to a second exemplary embodiment of the invention.

Referring to FIG. 4, as one example, the driving circuit unit 220 may set the pulse reset period PRP to one period between a start point of the reset period and a predetermined time.

Referring to FIG. 5, as another example, the driving circuit unit 220 may set the pulse reset period PRP to two periods consisting of one period between the start point of the reset period and a predetermined time and the other period from a time of the voltage level transition of the scan pulse signals Y1 to Ym within the reset period to a predetermined time.

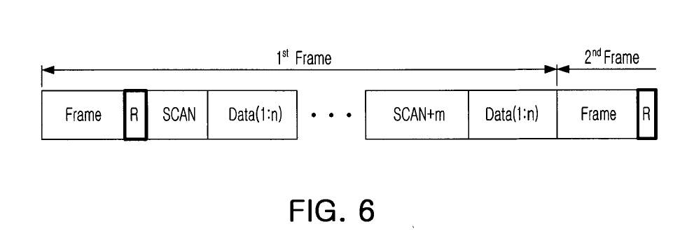

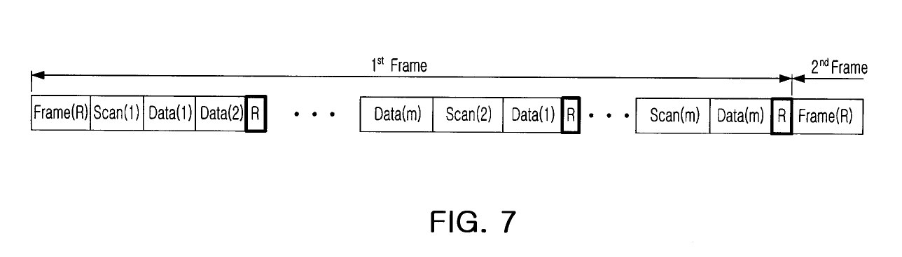

FIG. 6 is a view illustrating a first position example of a reset period of an electronic paper panel according to an exemplary embodiment. FIG. 7 is a view illustrating a second position example of a reset period of an electronic paper panel according to an exemplary embodiment.

Referring to FIG. 6, the reset period may be set next to the frame synchronization signal.

Referring to FIG. 7, the reset period may be set between the data pulse signals.

When the reset period is set next to the frame synchronization signal, the driving circuit unit 220 may generate the pulse reset signal that consists of the scan pulse signals Y1 to Ym at a high level corresponding to a positive voltage and one of the data pulse signals X1 to Xn and the upper electrode signal Z, the one signal having a plurality of pulses of alternating positive (+) and negative (−) voltages.

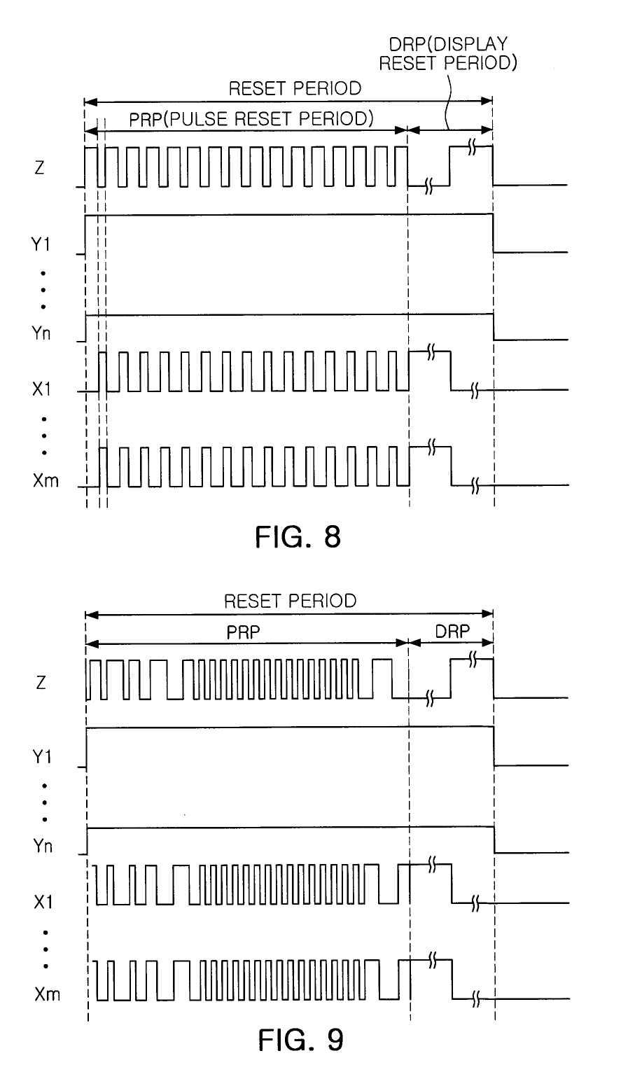

Examples thereof will now be described with reference to FIGS. 8 and 9.

FIG. 8 is an enlarged view illustrating a first example of a pulse reset signal according to an exemplary embodiment of the invention. Referring to FIG. 8, when the reset period is set next to the frame synchronization signal, the driving circuit unit 220 may generate the pulse reset signal that consists of the scan pulse signals Y1 to Ym at a high level corresponding to a positive voltage and the data pulse signals X1 to Xn and the upper electrode signal Z having a plurality of pulses with voltage levels opposite to each other.

FIG. 9 is an enlarged view illustrating a second example of a pulse reset signal according to an exemplary embodiment of the invention.

Referring to FIG. 9, the driving circuit unit 220 may generate the pulse reset signal that consists of the data pulse signals X1 to Xn and the upper electrode signal Z having duty cycles varying during the pulse reset period.

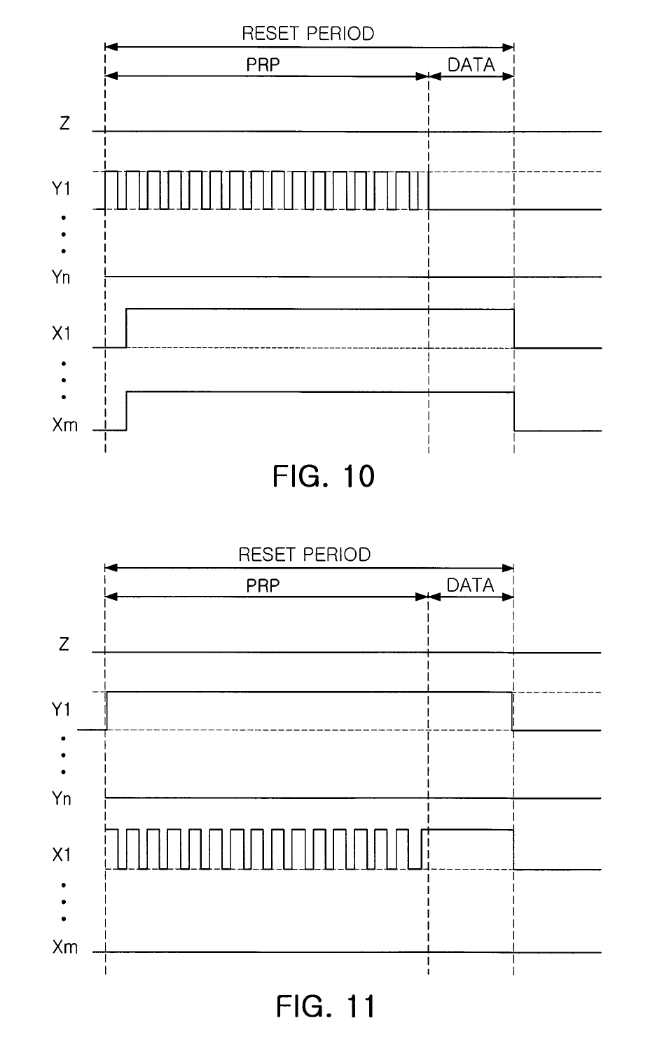

FIG. 10 is an enlarged view illustrating a third example of a pulse reset signal according to an exemplary embodiment of the invention. FIG. 11 is an enlarged view illustrating a fourth example of a pulse reset signal according to an exemplary embodiment of the invention.

Referring to FIG. 10, when the reset period is between the data pulse signals, the driving circuit unit 220 may generate the pulse reset signal that consists of the data pulse signals X1 to Xn at a high level corresponding to a positive voltage and the corresponding scan pulse signal Y1 having a plurality of pulses with a predetermined frequency among the scan pulse signals Y1 to Ym.

Referring to FIG. 11, when the reset period is between the data pulse signals, the driving circuit unit 220 may generate the pulse reset signal that consists of a corresponding scan pulse signal, for example, among the scan pulse signals Y1 to Ym at a high level corresponding to a positive voltage and the corresponding data pulse signal X1, for example, among the data pulse signals X1 to Xn, having a plurality of pulses with a predetermined frequency.

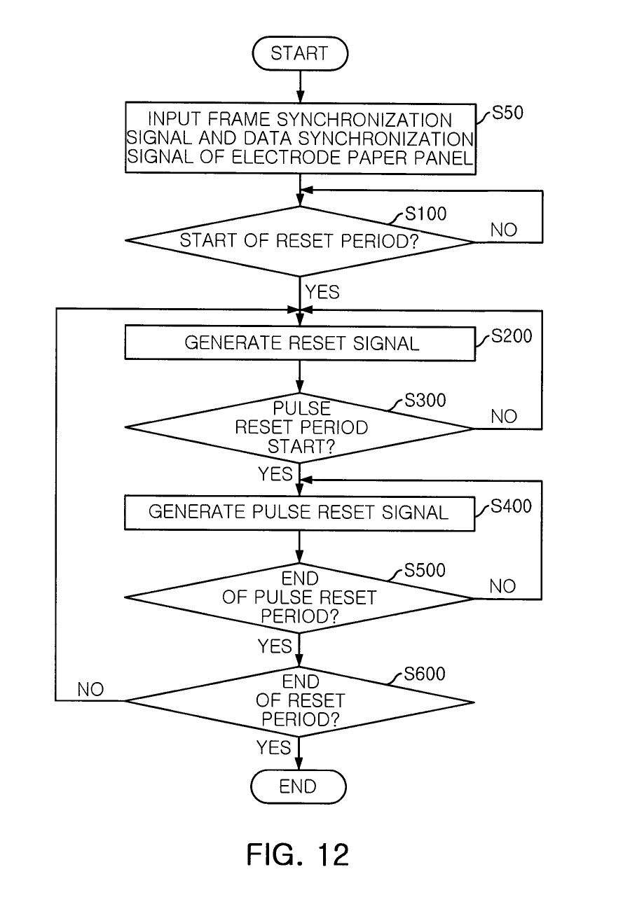

FIG. 12 is a flow chart illustrating a method of resetting an electronic paper panel according to an exemplary embodiment of the invention. Referring to FIG. 12, according to a method of resetting an electronic paper panel according to this embodiment, the start and end times of a predetermined reset period are determined using a frame synchronization signal and a data synchronization signal of an electronic paper panel in operation S100, a reset signal is generated during the reset period, determined in S100, in operation S200, the start and end times of a predetermined pulse reset period PRP within the reset period are determined in operation S300, and a pulse reset signal having pulses with a predetermined frequency during the pulse reset period PRP, determined in operation S200, in operation S400.

As described above, the resetting method according to this embodiment maybe realized in the driving circuit unit 220 of the electronic paper panel.

In operation S200 of generating a reset signal, a reset signal consisting of an upper electrode signal Z having a one-time voltage level transition, and scan pulse signals Y1 to Ym and data pulse signals X1 to Xn having the same voltage level to each other, opposite to that of the upper electrode signal Z, may be generated.

Here, in this embodiment of the invention, a voltage level transition refers to a voltage level conversion between a positive (+) voltage and a negative (−) voltage.

In operation S200 of generating a reset signal, a pulse reset signal that consists of at least one of the scan pulse signals Y1 to Ym, the data pulse signals X1 to Xn and the upper electrode signal Z, the at least one signal being a pulse signal having a plurality of pulses, may be generated.

Referring to FIGS. 4, 5, and 12, in operation S300 of determining a pulse reset period, the pulse reset period PRP may be set to one or more periods within the reset period.

Referring to FIGS. 4 and 12, in operation S300 of determining a pulse reset period, as one example, the pulse reset period PRP may be set to one period between a start point of the reset period and a predetermined time.

Referring to FIGS. 5 and 12, in operation S300 of determining a pulse reset period, as another example, the pulse reset period PRP may be set to two periods consisting of one period between the start point of the reset period and a predetermined time and the other period from a time of the voltage level transition of the scan pulse signals Y1 to Ym within the reset period to a predetermined time.

Referring to FIGS. 6, 7 and 12, the reset period may be set next to the frame synchronization signal or between the data pulse signals.

Referring to FIGS. 6 and 12, in operation S400 of generating a pulse reset signal, when the reset period is set next to the frame synchronization signal, the pulse reset signal that consists of the scan pulse signals Y1 to Ym at a high level corresponding to a positive voltage and one of the data pulse signals X1 to Xn and the upper electrode signal Z, the one signal having a plurality of pulses of alternating positive (+) and negative (−) voltages may be generated.

Here, in operation S400 of generating a pulse reset signal, a pulse reset signal having a duty cycle varying during the pulse reset period may be generated.

Referring to FIGS. 8 and 12, in operation S400 of generating a pulse reset signal, when the reset period is set next to the frame synchronization signal, the pulse reset signal that consists of the scan pulse signals Y1 to Ym at a high level corresponding to a positive voltage and the data pulse signals X1 to Xn and the upper electrode signal Z having a plurality of pulses with voltage levels opposite to each other may be generated.

Referring to FIGS. 9 and 12, in operation S400 of generating a pulse reset signal, the data pulse signals X1 to Xn and the upper electrode signal Z may consist of pulse signals duty cycles varying during the pulse reset period.

Referring to FIGS. 10 and 12, in operation S400 of generating a pulse reset signal, when the reset period is set between the data pulse signals, the pulse reset signal that consists of the data pulse signals X1 to Xn at a high level corresponding to a positive voltage and the corresponding scan pulse signal Y1 having a plurality of pulses with a predetermined frequency among the scan pulse signals Y1 to Ym may be generated.

Referring to FIGS. 11 and 12, in operation S400 of generating a pulse reset signal, when the reset signal is set between the data pulse signals, the pulse reset signal that consists of a corresponding scan pulse signal, for example, among the scan pulse signals Y1 to Ym at a high level corresponding to a positive voltage and the corresponding data pulse signal X1, for example, among the data pulse signals X1 to Xn, having a plurality of pulses with a predetermined frequency may be generated.

Hereinafter, the operation and effects of the invention will be described in detail with reference to the accompanying drawings.

The apparatus for resetting an electronic paper panel according to the exemplary embodiment of the invention will now be described with reference to FIGS. 1 through 11. First, referring to FIG. 1, the time control unit 210 of the apparatus for resetting an electronic paper panel determines the start and end times of a predetermined reset period on the basis of the frame synchronization signal and the data signal of the electronic paper panel from the control unit 100, and determines the start and end times of a predetermined pulse reset period within the PRP reset period within the reset period.

The driving circuit unit 220 according to this embodiment may generate a pulse reset signal having pulses with a predetermined frequency during the pulse reset period PRP, determined by the time control unit 210, and generate a display reset signal during a display reset period corresponding to the remaining period except for the pulse reset period in the reset period to thereby supply a reset signal having the pulse reset signal and the display reset signal to the electronic paper panel.

That is, in this embodiment, during the pulse reset period corresponding to a short period partially constituting the reset period, a pulse reset signal having a plurality of pulses of alternating positive (+) and negative (−) voltages is generated to thereby generate a new reset signal.

Referring to FIG. 2, the time control unit 210 according to this embodiment receives the frame synchronization signal F and the data signal D from the control unit 100 and generates a display reset signal and a pulse reset signal on the basis of the frame synchronization signal F and the data signal D to thereby supply the reset signal having the reset signal and the pulse reset signal to the electronic paper panel.

Here, the display reset signal and the pulse reset signal consist of scan pulse signals Y1 to Ym, data pulse signals X1 to Xn, and an upper electrode signal Z.

Referring to FIG. 1, the scan-line driver 222 of the driving circuit unit 220 may supply the scan pulse signals Y1 to Ym to the scan lines of the electronic paper panel, while the data-line driver 224 of the driving circuit unit 220 may supply the data pulse signals X1 to Xn to the data lines of the electronic paper panel and the upper electrode signal Z to the upper electrode 340 of the electronic paper panel.

Here, the display reset signal may consist of the upper electrode signal Z having a one-time voltage level transition, and the scan pulse signals Y1 to Ym and the data pulse signals X1 to Xn having the same voltage level to each other, opposite to that of the upper electrode signal Z.

Here, the pulse reset signal may consist of at least one of the scan pulse signals Y1 to Ym, the data pulse signals X1 to Xn and the upper electrode signal Z, the at least one signal being a pulse signal having a plurality of pulses of alternating positive (+) and negative (−) voltages.

Referring to FIG. 1, the electronic paper panel according to this embodiment may include the lower substrate 310, the lower electrode 320 formed on the lower substrate 310 and having a plurality of cells including a TFT array and electrodes, the ink substrate 330 formed on the lower electrode 320 and containing electronic ink, the transparent upper electrode 340 formed on the ink substrate 330, and the upper substrate 350 formed on the upper electrode 340.

Here, the electronic ink may be twist balls or electrophoretic capsules. When the electronic ink is twist balls, the ink substrate 330 may include separation walls formed between the twist balls.

Here, the driving circuit unit 220 supplies the upper electrode signal Z, included in the reset signal, to the upper electrode 340 of the electronic paper panel and supplies the scan pulse signals Y1 to Ym and the data pulse signals X1 to Xn, included in the reset signal, to the lower electrode 320 of the electronic paper panel.

One particular electrode of the lower electrode 320 may be electrically connected to the upper electrode 340 through an adhesive, so that the upper electrode signal Z may be supplied to the upper electrode 340 through the one particular electrode of the lower electrode 320.

The driving circuit unit 220 may set the pulse reset period PRP to one period within the reset period.

During the pulse reset period, when the pulse reset signal is supplied to the electronic paper panel, the electronic ink having an electrical polarity inside the electronic paper panel responds to the pulse reset signal for a short period of time, thereby improving the movement of the electronic ink.

Here, the reset period consists of the pulse reset period PRP and the display reset period DRP, corresponding to the remaining period except for the pulse reset period in the reset period.

When it comes to the number of pulse reset periods PRP, referring to FIG. 4, as one example, the driving circuit unit 220 may set the pulse reset period PRP to one period between a start point of the reset period and a predetermined time.

Referring to FIG. 5, as another example, the driving circuit unit 220 may set the pulse reset period PRP to two periods consisting of one period between the start point of the reset period and a predetermined time and the other period from the a time of the voltage level transition of the scan pulse signals Y1 to Ym within the reset period to a predetermined time.

For example, when the reset period is 700 msec, the pulse reset period PRP may be approximately 10 msec, and the display reset period DRP may be 690 msec.

As such, the pulse reset period is a very short period time of the time of the entire reset period. The movement of the electronic ink inside the electronic paper panel can be improved by the pulse reset signal having a plurality of pulses of alternating positive (+) and negative (−) voltages during this short period.

As for a position at which the reset period including the pulse reset period, as shown in FIG. 6, the reset period may be set next to the frame synchronization signal, and as shown in FIG. 7, the reset period may be set between the data pulse signals.

As shown in FIG. 6, when the reset period is set next to the frame synchronization signal, the driving circuit unit 220 may generate the pulse reset signal that consists of the scan pulse signals Y1 to Ym at a high level corresponding to a positive voltage and one of the data pulse signals X1 to Xn and the upper electrode signal Z, the one signal having a plurality of pulses of alternating positive (+) and negative (−) voltages.

A case in which the reset period is set next to the frame synchronization signal, as shown in FIG. 6, will now be described with reference to FIGS. 8 and 9.

Referring to FIG. 8, when the reset period is set next to the frame synchronization signal, the driving circuit unit 220 may generate the pulse reset signal that consists of the scan pulse signals Y1 to Ym at a high level corresponding to a positive voltage and the data pulse signals X1 to Xn and the upper electrode signal Z having a plurality of pulses with voltage levels opposite to each other.

As such, when the pulse reset signal is supplied to the electronic paper panel, the electronic ink having an electrical polarity inside the electronic paper panel responds to the pulse reset signal for a short period of time, thereby improving the movement of the electronic ink.

Furthermore, referring to FIG. 9, in order to further improve the movement of the electronic ink inside the electronic paper panel, the driving circuit unit 220 may generate the pulse reset signal that consists of the data pulse signals X1 to Xn and the upper electrode signal Z having duty cycles varying during the pulse reset period.

Meanwhile, as shown in FIG. 7, the driving circuit unit 220 may set the reset period between the data pulse signals. A case in which the reset period is set between the data pulse signals will now be described with reference to FIGS. 10 and 11.

Referring to FIG. 10, when the reset period is between the data pulse signals, the driving circuit unit 220 may generate the pulse reset signal that consists of the data pulse signals X1 to Xn at a high level corresponding to a positive voltage and the corresponding scan pulse signal Y1 having a plurality of pulses with a predetermined frequency among the scan pulse signals Y1 to Ym.

Referring to FIG. 11, when the reset period is between the data pulse signals, the driving circuit unit 220 may generate the pulse reset signal that consists of a corresponding scan pulse signal, for example, among the scan pulse signals Y1 to Ym at a high level corresponding to a positive voltage and the corresponding data pulse signal X1, for example, among the data pulse signals X1 to Xn, having a plurality of pulses with a predetermined frequency.

As such, as shown in FIGS. 10 and 11, when the pulse reset signal having a plurality of pulses of alternating positive and negative voltages is supplied, the electronic ink having an electrical polarity inside the electronic paper panel responds for a short period of time by the pulse reset signal, thereby improving the movement of the electronic ink.

Here, the pulse reset signal may be set to have a frequency of several tens or several hundreds of kHz. For example, the pulse reset signal may be a pulse signal having a frequency of 400 kHz.

Furthermore, the pulse reset signal may have a plurality of pulses of alternating positive (+) and negative (−) voltages on the basis of zero voltage. For example, the pulse reset signal has a maximum voltage of several tens of positive KHz voltage (V) and a minimum voltage of several tens of negative KHz voltage (V).

Here, the frequency of the pulse reset signal, and the maximum positive (+) voltage and the minimum negative (−) voltage of the pulse thereof may be set in order to improve the movement of the electronic ink.

Hereinafter, the method of resetting an electronic paper panel according to the exemplary embodiment of the invention will be described with reference to FIGS. 1 through 12.

Referring to FIG. 12, according to the method of resetting an electronic paper panel according to this embodiment, in operation S100 of determining a reset period, the start and end times of the predetermined reset period are determined on the basis of a frame synchronization signal and a data synchronization signal of the electronic paper panel.

Here, the reset period consists of the pulse reset period PRP and the display reset period DRP corresponding to the remaining period except for the pulse reset period in the reset period.

Then, in operation S200 of generating a reset signal, a reset signal is generated during the reset period determined in operation S100 of determining a reset period.

In operation S200 of generating a reset signal, a reset signal that consists of an upper electrode signal Z having a one-time voltage level transition, and scan pulse signals Y1 to Ym and data pulse signals X1 to Xn having the same voltage level to each other, opposite to that of the upper electrode signal Z, may be generated.

That is, in operation S200 of generating a reset signal, a pulse reset signal that consists of at least one of the scan pulse signals Y1 to Ym, the data pulse signals X1 to Xn and the upper electrode signal Z, the at least one signal being a pulse signal having a plurality of pulses, may be generated.

Then, in operation S300 of determining a pulse reset period, the start and end times of the predetermined pulse reset period PRP within the reset period are determined.

Referring to FIGS. 4, 5, and 12, in operation S300 of determining a pulse reset period, the pulse reset period PRP may be set to one period within the reset period.

Specifically, referring to FIGS. 4 and 12, in operation S300 of determining a pulse reset period, the pulse reset period PRP may be set to one period between a start point of the reset period and a predetermined time.

Referring to FIGS. 5 and 12, in operation S300 of determining a pulse reset period, the pulse reset period PRP may be set to one period from the start point of the reset period to the predetermined time and the other period from a time of the voltage level transition of the scan pulse signals Y1 to Ym within the reset period to a predetermined time.

In operation S400 of generating a pulse reset signal, a pulse reset signal having a plurality of pulses with a predetermined frequency is generated during the pulse reset period PRP, determined in operation S200 of determining a pulse reset period.

Referring to FIGS. 7, 8, and 12, the reset period may be set next to the frame synchronization signal or between the data pulse signals.

As one example, in operation S400 of generating a pulse reset signal, when the reset period is set next to the frame synchronization signal, the pulse reset signal that consists of the scan pulse signals Y1 to Ym at a high level corresponding to a positive voltage and one of the data pulse signals X1 to Xn and the upper electrode signal Z, the one signal having a plurality of pulses of alternating positive (+) and negative (−) voltages, may be generated.

Furthermore, in operation S400 of generating a pulse reset signal, the pulse reset signal having a duty cycle varying during the pulse reset period may be generated.

As another example, referring to FIGS. 8 and 12, in operation S400 of generating a pulse reset signal, when the reset period is set next to the frame synchronization signal, the pulse reset signal that consists of the scan pulse signals Y1 to Ym at a high level corresponding to a positive voltage and the data pulse signals X1 to Xn and the upper electrode signal Z having a plurality of pulses with voltage levels opposite to each other may be generated.

Furthermore, referring to FIGS. 9 and 12, in operation S400 of generating a pulse reset signal, the data pulse signals X1 to Xn and the upper electrode signal Z may include pulse signals having duty cycles varying during the pulse reset period.

Referring to FIGS. 10 and 12, in operation S400 of generating a pulse reset signal, when the reset period is set between the data pulse signals, the pulse reset signal that consists of the data pulse signals X1 to Xn at a high level corresponding to a positive voltage and the corresponding scan pulse signal Y1 having a plurality of pulses with a predetermined frequency among the scan pulse signals Y1 to Ym may be generated.

Referring to FIGS. 11 and 12, in operation S400 of generating a pulse reset signal, when the reset period is set between the pulse reset signals, the pulse reset signal that consists of a corresponding scan pulse signal, for example, among the scan pulse signals Y1 to Ym at a high level corresponding to a positive voltage and the corresponding data pulse signal X1, for example, among the data pulse signals X1 to Xn, having a plurality of pulses with a predetermined frequency may be generated.

As described above, when the pulse reset signal is supplied, the polarity of the electronic ink of the electronic paper panel changes repetitively for a short period of time due to the pulses of the pulse reset signal, thereby improving the movement of the electronic ink.

As set forth above, according to exemplary embodiments of the invention, a pulse reset signal having a plurality of pulses of alternating positive (+) and negative (−) voltages is supplied to an electronic paper panel during a pulse reset period corresponding to a predetermined period partially constituting a predetermined reset period, thereby improving the movements of balls for resetting a display in an electronic paper panel, and thus eliminating a memory effect a memory effect such as an afterimage.

While the present invention has been shown and described in connection with the exemplary embodiments, it will be apparent to those skilled in the art that modifications and variations can be made without departing from the spirit and scope of the invention as defined by the appended claims.

What is claimed is:

1. An apparatus for resetting an electronic paper panel, the apparatus comprising:
a time control unit determining start and end times of a predetermined reset period on the basis of a frame synchronization signal and a data synchronization signal of an electronic paper panel, and determining start and end times of a predetermined pulse reset period within the reset period; and
a driving circuit unit generating a pulse reset signal having pulses with a predetermined frequency during the pulse reset period, determined by the time control unit, and generating a display reset signal during the reset period to thereby supply a reset signal having the pulse reset signal and the display reset signal to the electronic paper panel.

2. The apparatus of claim 1, wherein the driving circuit unit comprises:
a scan-line driver supplying scan pulse signals to scan lines of a lower electrode included in the electronic paper panel; and
a data-line driver supplying data pulse signals to data lines of the lower electrode included in the electronic paper panel, and supplying an upper electrode signal to an upper electrode of the electronic paper panel,
wherein the display reset signal comprises the upper electrode signal having a one-time voltage level transition and the scan pulse signals and the data pulse signals having the same voltage level opposite to that of the upper electrode signal, and
the pulse reset signal comprises at least one of the scan pulse signals, the data pulse signals and the upper electrode signal, the at least one signal having a plurality of pulses.

3. The apparatus of claim 2, wherein the driving circuit unit sets the pulse reset period to one or more periods within the reset period.

4. The apparatus of claim 3, wherein the driving circuit unit sets the pulse reset period to one period between a start point of the reset period and a predetermined time.

5. The apparatus of claim 4, wherein the driving circuit unit sets the pulse reset period to two periods consisting of one period between the start point of the reset period and a predetermined time and the other period between a time of the voltage level transition of the scan pulse signals within the reset period and a predetermined time.

6. The apparatus of claim 3, wherein the reset period is set next to the frame synchronization signal or between the data pulse signals.

7. The apparatus of claim 6, wherein the driving circuit unit generates the pulse reset signal comprising the scan pulse signals at a high level corresponding to a positive voltage and one of the data pulse signals and the upper electrode signal, the one signal having a plurality of pulses of alternating positive (+) and negative (−) voltages.

8. The apparatus of claim 7, wherein the driving circuit unit generates the pulse reset signal having a duty cycle varying during the pulse reset period.

9. The apparatus of claim 6, wherein the driving circuit unit generates the pulse reset signal comprising the scan pulse signals at a high level corresponding to a positive voltage and the data pulse signals and the upper electrode signal having a plurality of pulses with voltage levels opposite to each other.

10. The apparatus of claim 9, wherein the driving circuit unit generates the pulse reset signal comprising the data pulse signals and the upper electrode signal having duty cycles varying during the pulse reset period.

11. The apparatus of claim 9, wherein the driving circuit unit generates the pulse reset signal comprising the data pulse signals at a high level corresponding to a positive voltage and a corresponding scan pulse signal, among the scan pulse signals, having a plurality of pulses with a predetermined frequency.

12. The apparatus of claim 9, wherein the driving circuit unit generates the pulse reset signal comprising a corresponding scan pulse signal at a high level corresponding to a positive voltage among the scan pulse signals and a corresponding data pulse signal having a plurality of pulses with a predetermined frequency among the data pulse signals.

13. A method of resetting an electronic paper panel, the method comprising:
a reset period determination operation of determining start and end times of a predetermined reset period on the basis of a frame synchronization signal and a data synchronization signal of an electronic paper frame;
a reset signal generation operation of generating a reset signal during the reset period determined in the reset period determination operation;
a pulse reset period determination operation of determining start and end times of a predetermined pulse reset period within the reset period; and
a pulse reset signal generation operation of generating a pulse reset signal having pulses with a predetermined frequency during the pulse reset period determined in the pulse reset period determination operation.

14. The method of claim 13, wherein the reset signal generation operation generates the reset signal comprising the upper electrode signal having a one-time voltage level transition and the scan pulse signals and the data pulse signals having the same voltage level opposite to that of the upper electrode signal.

15. The method of claim 14, wherein the pulse reset signal generation operation generates the pulse reset signal comprising at least one of the scan pulse signals, the data pulse signals and the upper electrode signal, the at least one signal comprising a pulse signal having a plurality of pulses.

16. The method of claim 15, wherein the pulse reset period determination operation sets the pulse reset period to one or more periods within the reset period.

17. The method of claim 16, wherein the pulse reset period determination operation sets the pulse reset period between a start point of the reset period and a predetermined time.

18. The method of claim 16, wherein the pulse reset period determination operation sets the pulse reset period to two periods consisting of one period between a start point of the reset period and a predetermined time and the other period between a time of the voltage level transition of the scan pulse signals within the reset period and a predetermined time.

19. The method of claim 16, wherein the reset period is set next to the frame synchronization signal or between the data pulse signals.

20. The method of claim 19, wherein the pulse reset signal generation operation generates the pulse reset signal comprising the scan pulse signals at a high level corresponding to a positive voltage and one of the data pulse signals and the upper electrode signal, the one signal having a plurality of pulses of alternating positive (+) and negative (−) voltages, when the reset period is set next to the frame synchronization signal.

21. The method of claim 19, wherein the pulse reset signal generation operation generates the pulse reset signal having a duty cycle varying during the pulse reset period.

22. The method of claim 19, wherein the pulse reset signal generation operation generates the pulse reset signal comprising the scan pulse signals at a high level corresponding to a positive voltage and the data pulse signals and the upper electrode signal having a plurality of pulses with voltage levels opposite to each other when the reset period is set next to the frame synchronization signal.

23. The method of claim 22, wherein in the pulse reset signal generation operation, the data pulse signals and the upper electrode signal are pulse signals having duty cycles varying during the pulse reset period.

24. The method of claim 22, wherein the pulse reset signal generation operation generates the pulse reset signal comprising the data pulse signals at a high level corresponding to a positive voltage and a corresponding scan pulse signal having a plurality of pulses with a predetermined frequency among the scan pulse signals when the reset period is set between the data pulse signals.

25. The method of claim 22, wherein the pulse reset signal generation unit generates the pulse reset signal comprising a corresponding scan pulse signal at a high level corresponding to a positive voltage among the scan pulse signals and a corresponding data pulse signal having a plurality of pulses with a predetermined frequency among the data pulse signals when the reset period is set between the data pulse signals.
